(19) United States
(12) Patent Application Publication
(10) Pub. No.: US 2026/0275574 A1
(43) Pub. Date: Sep. 17, 2026

(54) FABRICATION METHOD OF HIGH-ASPECT-RATIO DOUBLE-LAYER DIAMOND NANOSTRUCTURE

(71) Applicant: INSTITUTE OF PHYSICS, CHINESE ACADEMY OF SCIENCES, Beijing (CN)

(72) Inventors: Fang JIAO, Beijing (CN); Ou ZHANG, Beijing (CN); Sichen MI, Beijing (CN)

(21) Appl. No.: 19/561,656

(22) Filed: Mar. 10, 2026

(30) Foreign Application Priority Data
Mar. 14, 2025 (CN) 202510305974.9

(51) Int. Cl. C30B 33/12; B08B 3/08; B08B 3/10; C23C 14/02; C23C 14/04; C23C 14/18; C23C 14/30; C23C 14/35; C23C 14/58; C30B 29/04; G03F 7/00; G03F 7/038; G03F 7/039; G03F 7/095; G03F 7/16

(52) U.S. Cl. CPC C30B 33/12; B08B 3/08; B08B 3/106; C23C 14/021; C23C 14/042; C23C 14/18; C23C 14/30; C23C 14/35; C23C 14/5873; C30B 29/04; G03F 7/038; G03F 7/039; G03F 7/095; G03F 7/16; G03F 7/70383

(57) ABSTRACT

Provided is a fabrication method of a high-aspect-ratio double-layer diamond nanostructure, including: coating a surface of pretreated single crystal diamond with two layers of photoresist, and forming two layers of photoresist nanostructure patterns on the surface of the single crystal diamond via electron beam lithography combined with wet etching; performing first metal deposition on the surface of the single crystal diamond, stripping an upper layer of photoresist to expose the nanostructure pattern of a lower layer of photoresist, performing second metal deposition on the surface of the single crystal diamond, and stripping the lower layer of photoresist to obtain a pattern having nanostructures of two layers of metal masks; and carrying out two steps of reactive ion etching by utilizing the two layers of metal masks, with one-step wet etching conducted between the two steps of reactive ion etching, so as to obtain a target-sized double-layer diamond nanostructure pattern.

### CROSS-REFERENCE TO RELATED APPLICATIONS

The present application claims priority to Chinese patent application No. 202510305974.9 entitled “Fabrication Method of High-aspect-ratio Double-layer Diamond Nanostructure”, filed on March 14, 2025, the entire contents of which are incorporated herein by reference.

### TECHNICAL FIELD

The present disclosure relates to the technical field of quantum materials, and in particular, to a fabrication method of a high-aspect-ratio double-layer diamond nanostructure.

### BACKGROUND

Single crystal diamond has excellent material properties, such as extremely high thermal conductivity, mechanical hardness, optical transparency over almost the entire wavelength range, and nearly complete chemical inertness. Nitrogen vacancy (NV) and silicon vacancy (SiV) in diamond have attracted widespread attention in the fields such as quantum sensing and quantum information processing. However, the chemical inertness of diamond makes it difficult to achieve micro-nano processing by wet etching. In recent years, processing methods based on reactive ion etching, focused ion beam, ion beam etching and other technologies have been developed to enable the fabrication of various diamond micro-nano structures.

In current research, the mask size required for nanopillar etching is usually determined during a lithography process. It is particularly difficult to precisely modify the mask shape through a reactive ion etching process, and due to the low etching rate and selectivity of single crystal diamond, it is challenging to mass-produce high-aspect-ratio diamond nanopillars with sharp tips. Additionally, existing studies fail to accurately achieve high-aspect-ratio fabrication of double-layer single crystal diamond structures with adjustable dimensions.

Therefore, there is a need to propose a new technical solution to realize the repeatable, controllable, and mass fabrication of high-aspect-ratio double-layer diamond nanostructures, thereby solving the huge technical challenges faced by the wafer-level process manufacturing of the high-aspect-ratio double-layer single crystal diamond nanostructures with adjustable dimensions.

### SUMMARY

Based on the current research status, in order to solve or at least partially solve the huge technical challenges faced by the wafer-level process manufacturing of the high-aspect-ratio double-layer single crystal diamond nanostructures with adjustable dimensions in the related art, the present disclosure proposes a fabrication method of a high-aspect-ratio double-layer diamond nanostructure.

An objective of the present disclosure is to achieve the wafer-level process manufacturing of the high-aspect-ratio double-layer single crystal diamond nanostructures with adjustable dimensions.

A further objective of the present disclosure is to improve an aspect ratio of the single crystal diamond nanostructure and achieve the simple, efficient, repeatable, and low-cost manufacturing of the high-aspect-ratio double-layer diamond nanostructure.

In particular, the present disclosure provides a fabrication method of a high-aspect-ratio double-layer diamond nanostructure, including: performing surface pretreatment on single crystal diamond; coating a surface of the pretreated single crystal diamond with two layers of photoresist, and forming two layers of photoresist nanostructure patterns on the surface of the single crystal diamond via electron beam lithography combined with wet etching; performing first metal deposition on the surface of the single crystal diamond, stripping an upper layer of photoresist to expose the nanostructure pattern of a lower layer of photoresist, performing second metal deposition on the surface of the single crystal diamond, and stripping the lower layer of photoresist to obtain a pattern having nanostructures of two layers of metal masks; and carrying out two steps of reactive ion etching on the surface of the single crystal diamond by utilizing the two layers of metal masks, with one-step wet etching conducted between the two steps of reactive ion etching, so as to obtain a target-sized double-layer diamond nanostructure pattern.

Optionally, operations of the electron beam lithography include: exposing, according to a preset nanostructure pattern, the upper layer of photoresist via an electron beam lithography apparatus, and developing the upper layer of photoresist to obtain the nanostructure pattern of the upper layer of photoresist.

An operation of the wet etching includes: performing wet etching on the lower layer of photoresist until the nanostructure pattern of the lower layer of photoresist reaches a predetermined dimension.

Optionally, the upper layer of photoresist is polymethyl methacrylate, a polymethyl methacrylate-methyl methacrylate copolymer, or an acrylic copolymer, with a thickness of 100-200 nm; the lower layer of photoresist is polydimethylglutarimide or phenolic resin, with a thickness of 200-500 nm; and an etchant used in the wet etching is a weakly alkaline etchant, where the weakly alkaline etchant is a tetramethylammonium hydroxide solution with a concentration of 0.5-10 wt % or a sodium carbonate solution with a concentration of 1-10 g/L.

Optionally, after coating the surface of the pretreated single crystal diamond with the two layers of photoresist, the fabrication method further includes: coating a surface of the upper layer of photoresist with a conductive layer, with a thickness of the conductive layer being 10-30 nm.

Optionally, the two layers of metal masks include a second layer of metal mask deposited on the surface of the single crystal diamond and a first layer of metal mask covering and surrounding the second layer of metal mask; the first metal deposition and the second metal deposition are performed by electron beam evaporation or magnetron sputtering; the first layer of metal mask is made of chromium or aluminum, with a thickness of 100-300 nm; and the second layer of metal mask is made of titanium or gold, with a thickness of 30-150 nm.

Optionally, the step of carrying out two steps of reactive ion etching on the surface of the single crystal diamond by utilizing the two layers of metal masks, with one-step wet etching conducted between the two steps of reactive ion etching, so as to obtain the target-sized double-layer diamond nanostructure pattern includes: performing first reactive ion etching on the surface of the single crystal diamond until reaching a first designated etching height; performing wet etching using a wet etchant to remove the first layer of metal mask, the wet etchant offering high selectivity to the material of the first layer of metal mask and the material of the second layer of metal mask; and performing second reactive ion etching on the surface of the single crystal diamond until reaching a second designated etching height.

Optionally, the first reactive ion etching is implemented via inductively coupled plasma reactive ion etching, with process parameters set as follows: inductively coupled plasma power: 400-800 W, radio frequency power: 50-200 W, working pressure: 3-15 mTorr, oxygen flow rate: 20-50 sccm, etching time: 5-30 min, and etching rate: 150-200 nm/min.

In a case where the first layer of metal mask is made of chromium, the wet etchant is a mixed solution containing 5-10 vol % of 65-70% nitric acid solution, 30-50 g/L cerium ammonium nitrate, and deionized water; in a case where the first layer of metal mask is made of aluminum, the wet etchant is a tetramethylammonium hydroxide solution with a concentration of 0.5-10 wt %, and an etching rate of the wet etching is 5-20 nm/s.

The second reactive ion etching is implemented via inductively coupled plasma reactive ion etching, with process parameters set as follows: inductively coupled plasma power: 400-800 W, radio frequency power: 50-200 W, working pressure: 3-15 mTorr, oxygen flow rate: 20-50 sccm, etching time: 5-10 min, and etching rate: 150-200 nm/min.

Optionally, after completing the second reactive ion etching, the fabrication method further includes: removing the second layer of metal mask and cleaning the single crystal diamond with an acid solution, where in a case where the second layer of metal mask is made of titanium, removing the second layer of metal mask with a buffered oxide etchant, and in a case where the second layer of metal mask is made of gold, removing the second layer of metal mask with aqua regia; the acid solution is a mixture of concentrated sulfuric acid and concentrated nitric acid, with a volume ratio of concentrated sulfuric acid to concentrated nitric acid of 3:1; and the cleaning operation includes: placing the single crystal diamond in the acid solution and heating for acid boiling at 150-200° C.

Optionally, operations of surface pretreatment include: performing double-sided mechanical fine polishing on the single crystal diamond until a roughness Ra of the surface of the single crystal diamond is less than 1 nm; and conducting chemical treatment on the polished single crystal diamond to remove surface impurities, where the operation of the chemical treatment includes: placing the single crystal diamond in an acid solution and heating for acid boiling at 150-200° C., and the acid solution is a mixture of concentrated sulfuric acid and concentrated nitric acid, with a volume ratio of concentrated sulfuric acid to concentrated nitric acid of 3:1.

Optionally, prior to performing the electron beam lithography, the fabrication method further includes: cleaning the surface of the single crystal diamond, where the operations of the cleaning include: cleaning the single crystal diamond with a piranha solution; and subjecting the single crystal diamond to ultrasonic treatment sequentially with acetone, isopropanol, and deionized water.

According to the fabrication method of the high-aspect-ratio double-layer diamond nanostructure provided by the present disclosure, firstly, the two layers of photoresist nanostructure patterns are formed on the surface of the pretreated single crystal diamond by performing electron beam lithography combined with wet etching on the two layers of photoresist; then, the first metal deposition, stripping of upper layer of photoresist, second metal deposition and stripping of lower layer of photoresist are sequentially carried out on the surface of the single crystal diamond by using the two layers of photoresist nanostructure patterns to obtain the nanostructures of the two layers of metal masks; finally, the two layers of metal masks are employed to perform two steps of reactive ion etching and one-step wet etching, so as to obtain the target-sized double-layer nanostructure pattern; and therefore, the wafer-level process manufacturing of the double-layer single crystal diamond nanostructure is achieved.

Further, by controlling the sizes of the two layers of photoresist nanostructure patterns and thereby adjusting the sizes of the two layers of metal masks, the aspect ratio of the single crystal diamond nanostructure can be increased, so that the simple, efficient, repeatable, and low-cost fabrication of the high-aspect-ratio double-layer diamond nanostructure is realized.

Further, by adjusting the sizes of the two layers of metal masks and controlling the etching heights of the two steps of reactive ion etching, the dimension and morphology of the double-layer diamond nanostructure are enabled to be adjustable.

The above description is merely a summary of the technical solution of the present disclosure. To clearly understand the technical means of the present disclosure and implement the present disclosure in accordance with the content of the Description, and to make the above and other objectives, features and advantages of the present disclosure more obvious and understandable, specific embodiments of the present disclosure are specifically described below.

Based on the detailed description of specific embodiments of the present disclosure in conjunction with the accompanying drawings below, those skilled in the art will further clarify the above and other objectives, advantages and features of the present disclosure.

### BRIEF DESCRIPTION OF THE DRAWINGS

Upon reading the detailed description of the preferred embodiments hereinafter, various other advantages and benefits will become apparent to those of ordinary skill in the art. The accompanying drawings are only for the purpose of illustrating the preferred embodiments and are not to be construed as limiting the present disclosure. Moreover, the same reference numerals are used to denote the same components throughout the accompanying drawings. In figures:

FIG. 1 is a schematic flow chart illustrating a fabrication method of a high-aspect-ratio double-layer diamond nanostructure according to an embodiment of the present disclosure;

FIG. 2 is a schematic flow chart illustrating a fabrication method of a high-aspect-ratio double-layer diamond nanostructure according to another embodiment of the present disclosure;

FIG. 3a and FIG. 3b are optical microscope and electron microscope images for a dimensional characterization method of a nanostructure pattern of a lower layer of photoresist during wet etching according to an embodiment of the present disclosure;

FIG. 4 is a schematic diagram illustrating a processing flow of a high-aspect-ratio double-layer diamond nanostructure according to an embodiment of the present disclosure;

FIG. 5 is an electron microscope image of a fabricated double-layer diamond nanopillar waveguide according to an embodiment of the present disclosure (taken at a tilt angle of 45 degrees);

FIG. 6 is an electron microscope image of fabricated high-aspect-ratio double-layer diamond nanopillars with sharp tips according to an embodiment of the present disclosure (taken at a tilt angle of 45 degrees);

FIG. 7 shows electron microscope images of a variety of different double-layer metal mask nanostructures obtained according to some embodiments of the present disclosure (taken at a tilt angle of 0 degrees); and

FIG. 8a to FIG. 8e show electron microscope images of double-layer diamond nanostructures with different sizes and morphologies fabricated according to some embodiments of the present disclosure (taken at a tilt angle of 45 degrees).

### DETAILED DESCRIPTION OF THE EMBODIMENTS

The exemplary embodiments of the present disclosure will be described in more detail below with reference to the accompanying drawings. Although the exemplary embodiments of the present disclosure are shown in the accompanying drawings, it should be understood that the present disclosure can be implemented in various forms and should not be limited by the embodiments set forth herein. On the contrary, these embodiments are provided to enable a more thorough understanding of the present disclosure and to fully convey the scope of the present disclosure to those skilled in the art.

Based on the current research status, to address the huge technical challenges faced by the wafer-level process manufacturing of the high-aspect-ratio double-layer single crystal diamond nanostructures with adjustable dimensions, the present disclosure proposes a fabrication method of a high-aspect-ratio double-layer diamond nanostructure.

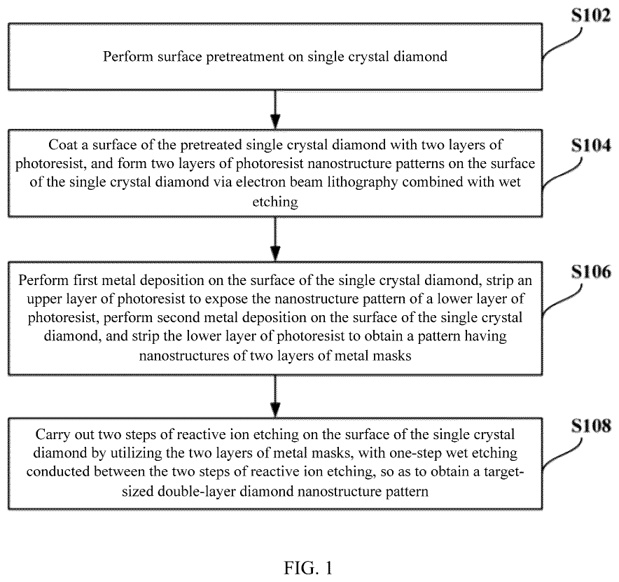

FIG. 1 is a schematic flow chart illustrating a fabrication method of a high-aspect-ratio double-layer diamond nanostructure according to an embodiment of the present disclosure. Referring to FIG. 1, the fabrication method may at least include following steps S102 to S108:
step S102: performing surface pretreatment on single crystal diamond;
S104: coating a surface of the pretreated single crystal diamond with two layers of photoresist, and forming two layers of photoresist nanostructure patterns on the surface of the single crystal diamond via electron beam lithography combined with wet etching;
step S106: performing first metal deposition on the surface of the single crystal diamond, stripping an upper layer of photoresist to expose the nanostructure pattern of a lower layer of photoresist, performing second metal deposition on the surface of the single crystal diamond, and stripping the lower layer of photoresist to obtain a pattern having nanostructures of two layers of metal masks; and
step S108: carrying out two steps of reactive ion etching on the surface of the single crystal diamond by utilizing the two layers of metal masks, with one-step wet etching conducted between the two steps of reactive ion etching, so as to obtain a target-sized double-layer diamond nanostructure pattern.

In this embodiment, firstly, the two layers of photoresist nanostructure patterns are formed on the surface of the pretreated single crystal diamond by performing electron beam lithography combined with wet etching on the two layers of photoresist; then, the first metal deposition, stripping of upper layer of photoresist, second metal deposition and stripping of lower layer of photoresist are sequentially carried out on the surface of the single crystal diamond by using the two layers of photoresist nanostructure patterns to obtain the nanostructures of the two layers of metal masks; finally, the two layers of metal masks are employed to perform two steps of reactive ion etching and one-step wet etching, so as to obtain the target-sized double-layer nanostructure pattern; and therefore, the wafer-level process manufacturing of the double-layer single crystal diamond nanostructure is achieved.

In some embodiments, the operations of surface pretreatment in step S102 may include: first, performing double-sided mechanical fine polishing on the single crystal diamond, specifically to make a roughness Ra of the surface of the single crystal diamond less than 1 nm; and then, conducting chemical treatment on the polished single crystal diamond to remove surface impurities. The surface impurities include surface contaminants and metal impurities introduced during the polishing process.

Specifically, the operation of chemical treatment includes: placing the single crystal diamond in an acid solution and heating for acid boiling at 150-200° C. Optionally, the acid solution is a mixture of concentrated sulfuric acid and concentrated nitric acid, with a volume ratio of concentrated sulfuric acid to concentrated nitric acid of 3:1. The commonly used concentrated sulfuric acid with a mass fraction of 98% may be adopted as the concentrated sulfuric acid. The commonly used concentrated nitric acid with a mass fraction of approximately 65% may be adopted as the concentrated nitric acid.

After the surface pretreatment, a clean single crystal diamond substrate with finely polished surface and high flatness is obtained.

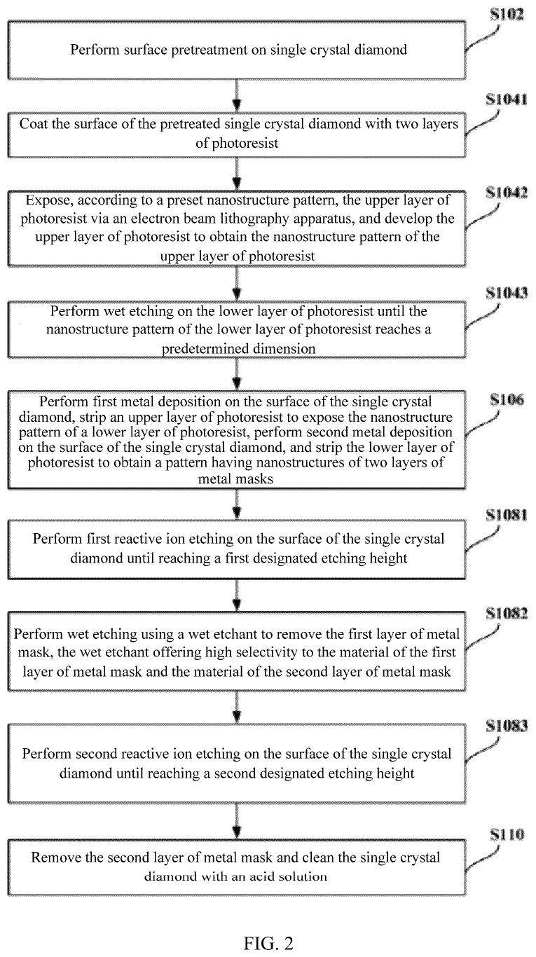

FIG. 2 is a schematic flow chart illustrating a fabrication method of a high-aspect-ratio double-layer diamond nanostructure according to another embodiment of the present disclosure.

Referring to FIG. 2, in some embodiments, step S104 may include:
step S1041: coating the surface of the pretreated single crystal diamond with two layers of photoresist to form a lower layer of photoresist and an upper layer of photoresist stacked on the surface of the single crystal diamond;
step S1042 (electron beam lithography step): exposing, according to a preset nanostructure pattern, the upper layer of photoresist via an electron beam lithography apparatus, and developing the upper layer of photoresist to obtain the nanostructure pattern of the upper layer of photoresist; and
step S1043 (wet etching step): performing wet etching on the lower layer of photoresist until the nanostructure pattern of the lower layer of photoresist reaches a predetermined dimension.

In some embodiments, one surface of the pretreated single crystal diamond is coated with two layers of photoresist by a spin-coating process in step S1041.

In some specific embodiments, the upper layer of photoresist may be polymethyl methacrylate (PMMA, e.g., PMMA 495A5), a polymethyl methacrylate-methyl methacrylate copolymer (PMMA-MAA), or an acrylic copolymer (e.g., ma-N). The thickness of the upper layer of photoresist may be in a range of 100-200 nm, such as 120 nm, 150 nm, and 180 nm.

The lower layer of photoresist may be phenolic resin (e.g., LOR1A) or polydimethylglutarimide (PMGI). The thickness of the lower layer of photoresist may be in a range of 200-500 nm, such as 200 nm, 250 nm, 350 nm, 450 nm, and 500 nm.

In some alternative embodiments, after coating the surface of the pretreated single crystal diamond with the two layers of photoresist, the fabrication method provided by the present disclosure further includes: coating a surface of the upper layer of photoresist with a conductive layer to suppress the charging effect during the electron beam exposure process. The thickness of the conductive layer may be in a range of 10-30 nm, such as 10 nm, 20 nm, and 30 nm. The conductive layer may be made of Eltra92, for example.

In some alternative embodiments, prior to performing the electron beam lithography, the fabrication method provided by the present disclosure further includes: cleaning the surface of the single crystal diamond.

Specifically, the operations of the cleaning treatment include: first, cleaning the single crystal diamond with a piranha solution, specifically for about 30 min, to remove organic matters on the surface of the single crystal diamond; and then, subjecting the single crystal diamond to ultrasonic treatment sequentially with acetone, isopropanol, and deionized water, with an ultrasonic treatment time for each solvent being 5-10 min. Afterwards, the surface of the single crystal diamond may also be blown dry with nitrogen.

The electron beam exposure of the upper layer of photoresist in step S1042 may be performed by a conventional exposure operation. In a specific embodiment, the exposure energy of the electron beam exposure is 100 kv, and the exposure dose is 800-1500 μc·cm⁻².

A conventional developing operation may be used for developing treatment, for example, a mixed solution of methyl isobutyl ketone (MIBK) and isopropanol (IPA) in a ratio of 1:3 is used as a developer for the developing treatment, with a development time of 50 s.

After the completion of developing, the substrate may also be rinsed in an isopropanol solution and blown dry with nitrogen to obtain the desired nanostructure pattern of the upper layer of photoresist.

In some specific embodiments, the nanostructure pattern of the upper layer of photoresist is a nanopore structure pattern. The pore diameters of nanopores range from 30 nm to 150 nm, such as 30 nm, 40 nm, 50 nm, 60 nm, 70 nm, 80 nm, 90 nm, 100 nm, 110 nm, 120 nm, 130 nm, and 140 nm. The period of the nanopores is in a range of 2-5 μm, for example, 2 μm, 3 μm, and 4 μm.

In some embodiments, an etchant used in the wet etching in step S1043 is a weakly alkaline etchant. In a specific embodiment, the weakly alkaline etchant is a mixed solution of tetramethylammonium hydroxide (TMAH) and deionized water, with a concentration of 0.5-10 wt %, such as 1.2 wt %, 2.2 wt %, 4 wt %, 5 wt %, and 6 wt %. In another specific embodiment, the weakly alkaline etchant is a sodium carbonate solution with a concentration of 1-10 g/L.

The specific size of the pattern of the lower layer of photoresist is related to the pattern design of the upper layer of photoresist and the processing time of the wet etching. In actual operation, the pattern of the lower layer of photoresist may be observed through an electron microscope or an optical microscope to determine whether the wet etching of the lower layer of photoresist has reached the end point (i.e., whether the nanostructure pattern of the lower layer of photoresist has reached a predetermined dimension). The predetermined dimension of the lower layer of photoresist pattern is related to the size of a large-sized portion in the double-layer nanostructure to be prepared, and can be specifically set according to actual requirements.

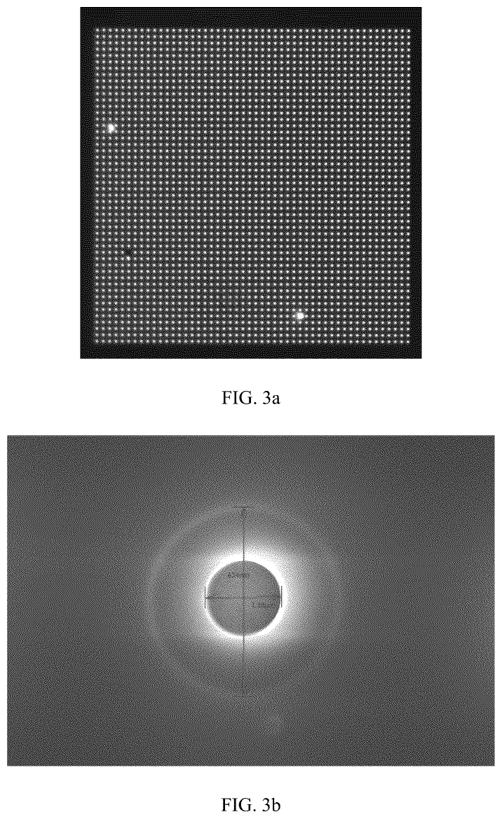

FIG. 3a and FIG. 3b are optical microscope and electron microscope images for a dimensional characterization method of a nanostructure pattern of the lower layer of photoresist during wet etching according to an embodiment of the present disclosure. In a specific embodiment, as shown in FIG. 3a, the end point of etching to a bottom layer may be determined by using the dark-field mode of a commercial optical microscope; and further, as shown in FIG. 3b, the specific etched dimensions (as indicated by the long double-headed arrow lines) may be measured by an electron microscopy, thereby determining the etching time.

In some embodiments, the two layers of metal masks obtained in step S106 include a second layer of metal mask deposited on the surface of the single crystal diamond and a first layer of metal mask covering and surrounding the second layer of metal mask.

In some embodiments, the first layer of metal mask and the second layer of metal mask may be formed into a self-aligned double-layer metal mask stack structure.

In some embodiments, the first metal deposition and the second metal deposition may be performed by electron beam evaporation or magnetron sputtering.

The first layer of metal mask and the second layer of metal mask may be made of high-selectivity hard mask materials.

In some specific embodiments, the material of the first layer of metal mask may be selected from chromium (Cr) or aluminum (Al). The thickness of the first layer of metal mask may be in a range of 100-300 nm, such as 120 nm, 150 nm, 180 nm, 200 nm, 220 nm, 250 nm, and 300 nm.

The material of the second layer of metal mask may be selected from titanium (Ti) or gold (Au). The thickness of the second layer of metal mask may be in a range of 30-150 nm, such as 50 nm, 60 nm, 70 nm, 80 nm, 90 nm, 100 nm, 110 nm, 120 nm, 130 nm, and 140 nm.

In step S106 described above, after completing the first metal deposition, the upper layer of photoresist is stripped until the excess metal and photoresist of the upper pattern are completely removed. In some embodiments, the stripping of the upper layer of photoresist is performed using a first specific liquid. The first specific liquid may be, for example, acetone or anisole.

After stripping the upper layer of photoresist, the surface of the single crystal diamond may also be rinsed with isopropanol until the undercut generated by the wet etching of the lower layer of photoresist is fully exposed.

After completing the second metal deposition, the lower layer of photoresist is stripped to remove the metal layer not attached to the single crystal diamond substrate, and the self-aligned double-layer metal mask stack structure is ultimately obtained. In some embodiments, the stripping of the lower layer of photoresist is performed using a second specific liquid. The second specific liquid may be, for example, N, N-dimethyl sulfoxide (DMSO).

Continuing to refer to FIG. 2, in some embodiments, step S108 may include:
step S1081: performing first reactive ion etching on the surface of the single crystal diamond until reaching a first designated etching height;
step S1082: performing wet etching using a wet etchant to remove the first layer of metal mask, the wet etchant offering high selectivity to the material of the first layer of metal mask and the material of the second layer of metal mask; and
step S1083: performing second reactive ion etching on the surface of the single crystal diamond until reaching a second designated etching height.

Those skilled in the art will understand that an etching height refers to a distance from an etching start surface to an etching stop surface.

During the implementation of step S108, a scanning electron microscope (SEM) may be employed to monitor the etching process to determine whether the required etching height is met.

In some embodiments, the first reactive ion etching is implemented via inductively coupled plasma reactive ion etching (ICP-RIE). Specifically, the process parameters of the first reactive ion etching are set as follows: inductively coupled plasma power: 400-800 W, radio frequency power: 50-200 W, working pressure: 3-15 mTorr, oxygen flow rate: 20-50 sccm, etching time: 5-30 min, and etching rate: 150-200 nm/min.

In step S1082, the wet etchant offering high selectivity to the material of the first layer of metal mask and the material of the second layer of metal mask is employed for wet etching, thereby enabling the removal of the first layer of metal mask without damaging the second layer of metal mask.

In some embodiments, in a case where the first layer of metal mask is made of chromium, a mixed solution containing 5-10 vol % of 65-70% nitric acid solution, 30-50 g/L cerium ammonium nitrate, and deionized water is used in step S1082 to selectively remove the mask.

In some other embodiments, in a case where the first layer of metal mask is made of aluminum, a tetramethylammonium hydroxide solution with a concentration of 0.5-10 wt % is used as the wet etchant in step S1082.

Specifically, the etching rate of the first layer of metal mask may be in a range of 5-20 nm/s, for example, 5 nm/s, 10 nm/s, and 15 nm/s.

After wet etching is performed to remove the first layer of metal mask, the etched single crystal diamond may be sufficiently rinsed with deionized water and blown dry with nitrogen.

In some embodiments, the second reactive ion etching is implemented via inductively coupled plasma reactive ion etching, and the process parameters thereof are set as follows: inductively coupled plasma power: 400-800 W, radio frequency power: 50-200 W, working pressure: 3-15 mTorr, oxygen flow rate: 20-50 sccm, etching time: 5-10 min, and etching rate: 150-200 nm/min.

Continuing to refer to FIG. 2, in some embodiments, after completing the second reactive ion etching, the fabrication method provided by the present disclosure further includes:
step S110: removing the second layer of metal mask and cleaning the single crystal diamond with an acid solution to complete a final cleaning treatment of the etched single crystal diamond.

In some embodiments, in a case where the second layer of metal mask is made of titanium, the second layer of metal mask is removed using a buffered oxide etchant (BOE). Those skilled in the art will recognize that the buffered oxide etchant is prepared by mixing a 49% hydrogen fluoride (HF) aqueous solution and a 40% NH₄F aqueous solution at a volume ratio of 1:6.

In some other embodiments, in a case where the second layer of metal mask is made of gold, the second layer of metal mask is removed using aqua regia. Aqua regia is a mixture of concentrated hydrochloric acid and concentrated nitric acid at a volume ratio of 3:1.

In some embodiments, the acid solution used for cleaning is a mixture of concentrated sulfuric acid and concentrated nitric acid, with a volume ratio of concentrated sulfuric acid to concentrated nitric acid of 3:1. The commonly used concentrated sulfuric acid with a mass fraction of 98% may be adopted as the concentrated sulfuric acid. The commonly used concentrated nitric acid with a mass fraction of approximately 65% may be adopted as the concentrated nitric acid.

The cleaning operation includes: placing the single crystal diamond in the acid solution and heating for acid boiling at 150-200° C. to remove the residual metal mask, and ultimately obtaining a single crystal diamond structure with double-layer nanostructure patterns on its surface.

According to the present disclosure, by controlling the sizes of the two layers of photoresist nanostructure patterns and thereby adjusting the sizes of the two layers of metal masks, the aspect ratio of the single crystal diamond nanostructure can be increased, so that the simple, efficient, repeatable, and low-cost fabrication of the high-aspect-ratio double-layer diamond nanostructure is realized.

In the embodiments of the present disclosure, by adjusting the sizes of the two layers of metal masks and controlling the etching heights of the two steps of reactive ion etching, the dimension and morphology of the double-layer diamond nanostructure are enabled to be adjustable.

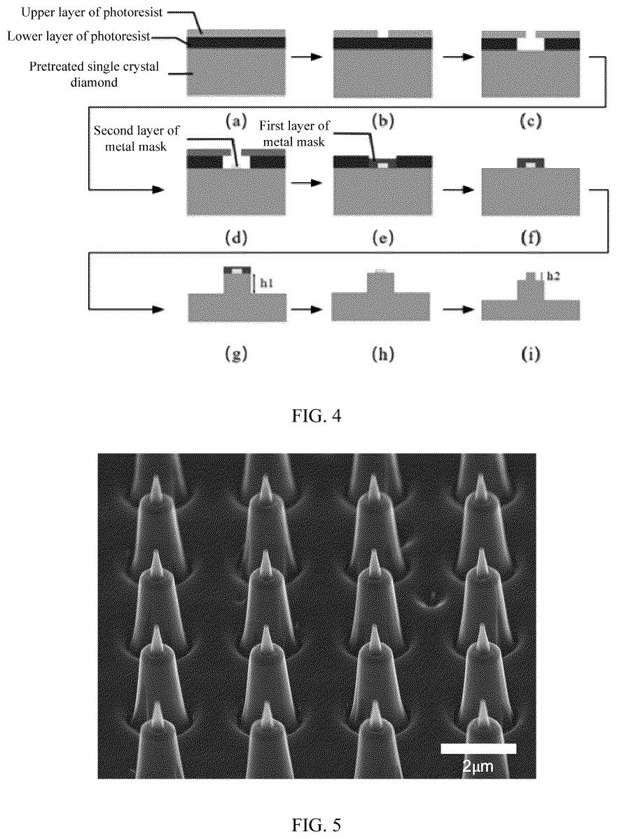

FIG. 4 is a schematic diagram illustrating a processing flow of a high-aspect-ratio double-layer diamond nanostructure (specifically, double-layer nanopillars) according to an embodiment of the present disclosure. In conjunction with FIG. 4, the fabrication method of the high-aspect-ratio double-layer diamond nanostructure provided by the present disclosure will be described in detail through a specific embodiment.

Step (a) in FIG. 4 shows the formation of two layers of photoresist on a single crystal diamond substrate. Before forming the two layers of photoresist, double-sided mechanical fine polishing is first performed on the single crystal diamond, and roughness requirement for the polished surface of the diamond is Ra<1 nm; and after polishing is finished, the diamond is heated for acid boiling (at 150-200° C.) in a mixed solution of concentrated sulfuric acid and concentrated nitric acid (in a volume ratio of 3:1), with a mass fraction of the concentrated sulfuric acid used being 98% and a mass fraction of the concentrated nitric acid used being 65%, until the surface contaminants and metal impurities introduced during the polishing process are completely removed, yielding a clean single crystal diamond substrate with a finely polished surface. Subsequently, the single crystal diamond that has been finely polished on both sides is used as the substrate, and is cleaned with a piranha solution for 30 min to remove organic matters on the surface of the substrate. Afterwards, the substrate is sequentially subjected to ultrasonic treatment with acetone, isopropanol, and deionized water for 5-10 min each, and the surface of the single crystal diamond is blown dry with nitrogen.

In this embodiment, a double-layer photoresist system composed of polymethyl methacrylate (PMMA, 495A5) and phenolic resin (LOR1A) is adopted. First, by optimizing a spin-coating process, a photoresist layer is formed on the single crystal diamond substrate, where PMMA (495A5) serves as the upper layer of photoresist with a thickness of 120 nm, and LOR1A serves as the lower layer of photoresist with a thickness of 350 nm. In addition, a 20 nm-thick conductive layer is spin-coated on the surface of the photoresist to suppress the charging effect during the electron beam exposure process.

Step (b) illustrates the electron beam lithography process. An electron beam lithography apparatus is adopted to expose the upper layer of photoresist to write in the designed nanostructure pattern, which defines a nanopore structure pattern with varied sizes and periods (pore diameter range: 30-150 nm; period range: 2-4 μm). A mixed solution of methyl isobutyl ketone (MIBK) and isopropanol (IPA) at a volume ratio of 1:3 is used as a developer for the developing process. After the development is completed, the substrate is rinsed in an IPA solution and blown dry with N₂ gas to obtain the desired nanostructured pattern of upper layer of photoresist.

Step (c) illustrates the wet etching process for the lower layer of photoresist. A tetramethylammonium hydroxide (TMAH) solution with a concentration of 2.2 wt % is used for etching the lower layer of photoresist. During the etching process, the pattern of the lower layer of photoresist is observed via an electron microscope or optical microscope to determine the end point of etching, and finally the desired pattern of lower layer of photoresist is obtained.

Steps (d) to (f) illustrate the process for forming the two layers of metal masks. In this embodiment, two hard masks made of different materials are adopted. Titanium (Ti) and chromium (Cr), which are high-selectivity hard mask materials suitable for the diamond reactive ion etching (RIE) process, are used as the two mask materials. Specifically, 80 nm-thick Ti is deposited by electron beam evaporation to form the second layer of metal mask, and the upper layer of photoresist is stripped using acetone or anisole, followed by rinsing with isopropanol, until the undercut generated by the wet etching of the lower layer of photoresist is fully exposed. Subsequently, 150 nm-thick Cr is deposited by electron beam evaporation to form the first layer of metal mask. Finally, the lower layer of photoresist is stripped using N, N-dimethyl sulfoxide (DMSO) to remove the metal layer not attached to the substrate, and a self-aligned double-layer metal mask structure is obtained ultimately.

Steps (g) to (i) illustrate the process flow of two steps of reactive ion etching (RIE) and one-step wet etching for fabricating the double-diameter nanopillar structure. First, Oxford Plasma 100 inductively coupled plasma (ICP) etching equipment is used for a first etching of large-diameter nanopillars (i.e., a first reactive ion etching), with the etching process parameters set as follows: inductively coupled plasma power: 600 W, radio frequency power: 150 W, working pressure: 5 mTorr, oxygen flow rate: 30 sccm, etching time: approximately 15 min, etching rate: approximately 200 nm/min, and a first designated etching height: h1. After etching is completed, a mixed solution of nitric acid (HNO₃) and cerium ammonium nitrate (Ce(NO₃)₄) is adopted for the selective removal of the mask (i.e., only removing the Cr mask), with a removal rate of about 5 nm/s, and then, the mask is thoroughly rinsed in deionized water and dried with nitrogen (N₂). On this basis, a second step of etching of small-diameter nanopillars (i.e., a second reactive ion etching) is carried out, with the etching process parameters set as follows: inductively coupled plasma power: 600 W, radio frequency power: 100 W, working pressure: 6 mTorr, oxygen flow rate: 25 sccm, etching time: approximately 6 min, etching rate: approximately 180 nm/min, and a second designated etching height h2. After etching is completed, the Ti mask is removed using the buffered oxide etchant (BOE) solution, and the single crystal diamond is cleaned in the mixture of concentrated sulfuric acid and concentrated nitric acid (in a volume ratio of 3:1) by heating for acid boiling (at 150-200° C.) to remove residues.

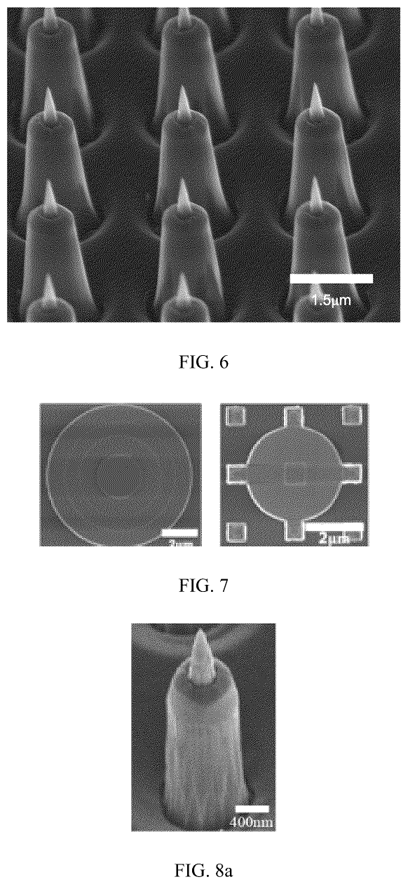

FIG. 5 is an electron microscope image of a fabricated double-layer diamond nanopillar waveguide according to an embodiment of the present disclosure (taken at a tilt angle of 45 degrees). FIG. 6 is an electron microscope image of fabricated high-aspect-ratio double-layer diamond nanopillars with sharp tips according to an embodiment of the present disclosure (taken at a tilt angle of 45 degrees). As can be seen from FIG. 5 and FIG. 6, high-quality high-aspect-ratio double-layer diamond nanopillars are obtained via the fabrication method according to the embodiments of the present disclosure.

Certainly, in other embodiments of the present disclosure, the two layers of photoresist can also be patterned with nanostructures of other different sizes and shapes, so as to obtain double-layer metal mask nanostructures with other varied sizes and shapes, and further achieve double-layer diamond nanostructures with diverse sizes and morphologies.

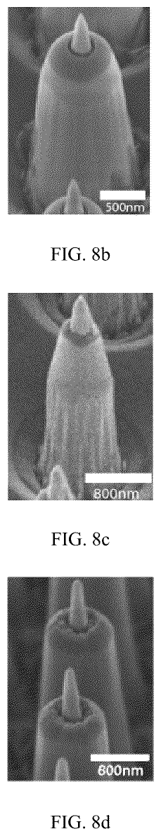

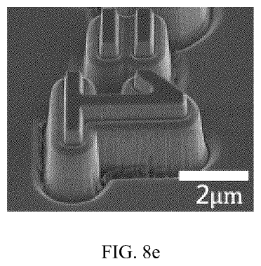

FIG. 7 schematically shows electron microscope images of a variety of different double-layer metal mask nanostructures obtained according to some embodiments of the present disclosure (taken at a tilt angle of 0 degrees). FIG. 8 a to FIG. 8 e schematically show electron microscope images of double-layer diamond nanostructures with different sizes and morphologies fabricated according to some embodiments of the present disclosure (taken at a tilt angle of 45 degrees).

As can be seen from FIG. 7 and FIG. 8a to FIG. 8e, the fabrication method provided by the present disclosure offers feasibility in the control and flexibility in the fabrication of a variety of double-layer diamond nanostructures. In particular, FIG. 8c and FIG. 8d indicate that the technical solution provided by the present disclosure can achieve universality for different nanostructures.

In the Description provided herein, numerous specific details are set forth. However, it should be understood that the embodiments of the present disclosure may be practiced without these specific details. In some examples, well-known methods, structures, and techniques have not been described in detail so as not to obscure the understanding of this Description.

Hereto, those skilled in the art should realize that although a plurality of exemplary embodiments of the present disclosure have been shown and described in detail herein, without departing from the spirit and scope of the present disclosure, many other variations or modifications that conform to the principles of the present disclosure can still be directly determined or deduced from the contents disclosed in the present disclosure. Therefore, the scope of the present disclosure should be understood and recognized as covering all these other variations or modifications.

What is claimed is:

1. A fabrication method of a high-aspect-ratio double-layer diamond nanostructure, comprising:
performing surface pretreatment on single crystal diamond;
coating a surface of the pretreated single crystal diamond with two layers of photoresist, and forming two layers of photoresist nanostructure patterns on the surface of the single crystal diamond via electron beam lithography combined with wet etching;
performing first metal deposition on the surface of the single crystal diamond, stripping an upper layer of photoresist to expose the nanostructure pattern of a lower layer of photoresist, performing second metal deposition on the surface of the single crystal diamond, and stripping the lower layer of photoresist to obtain a pattern having nanostructures of two layers of metal masks; and
carrying out two steps of reactive ion etching on the surface of the single crystal diamond by utilizing the two layers of metal masks, with one-step wet etching conducted between the two steps of reactive ion etching, so as to obtain a target-sized double-layer diamond nanostructure pattern.

2. The fabrication method of the high-aspect-ratio double-layer diamond nanostructure according to claim 1, wherein operations of the electron beam lithography comprise:
exposing, according to a preset nanostructure pattern, the upper layer of photoresist via an electron beam lithography apparatus, and developing the upper layer of photoresist to obtain the nanostructure pattern of the upper layer of photoresist; and
an operation of the wet etching comprises:
performing wet etching on the lower layer of photoresist until the nanostructure pattern of the lower layer of photoresist reaches a predetermined dimension.

3. The fabrication method of the high-aspect-ratio double-layer diamond nanostructure according to claim 2, wherein
the upper layer of photoresist is polymethyl methacrylate, a polymethyl methacrylate-methyl methacrylate copolymer, or an acrylic copolymer, with a thickness of 100-200 nm; the lower layer of photoresist is polydimethylglutarimide or phenolic resin, with a thickness of 200-500 nm; and
an etchant used in the wet etching is a weakly alkaline etchant, wherein the weakly alkaline etchant is a tetramethylammonium hydroxide solution with a concentration of 0.5-10 wt % or a sodium carbonate solution with a concentration of 1-10 g/L.

4. The fabrication method of the high-aspect-ratio double-layer diamond nanostructure according to claim 1, wherein after coating the surface of the pretreated single crystal diamond with the two layers of photoresist, the fabrication method further comprises:
coating a surface of the upper layer of photoresist with a conductive layer, with a thickness of the conductive layer being 10-30 nm.

5. The fabrication method of the high-aspect-ratio double-layer diamond nanostructure according to claim 1, wherein the two layers of metal masks comprise a second layer of metal mask deposited on the surface of the single crystal diamond and a first layer of metal mask covering and surrounding the second layer of metal mask;
the first metal deposition and the second metal deposition are performed by electron beam evaporation or magnetron sputtering;
the first layer of metal mask is made of chromium or aluminum, with a thickness of 100-300 nm; and
the second layer of metal mask is made of titanium or gold, with a thickness of 30-150 nm.

6. The fabrication method of the high-aspect-ratio double-layer diamond nanostructure according to claim 5, wherein the step of carrying out two steps of reactive ion etching on the surface of the single crystal diamond by utilizing the two layers of metal masks, with one-step wet etching conducted between the two steps of reactive ion etching, so as to obtain the target-sized double-layer diamond nanostructure pattern comprises:
performing first reactive ion etching on the surface of the single crystal diamond until reaching a first designated etching height;
performing wet etching using a wet etchant to remove the first layer of metal mask, the wet etchant offering high selectivity to the material of the first layer of metal mask and the material of the second layer of metal mask; and
performing second reactive ion etching on the surface of the single crystal diamond until reaching a second designated etching height.

7. The fabrication method of the high-aspect-ratio double-layer diamond nanostructure according to claim 6, wherein the first reactive ion etching is implemented via inductively coupled plasma reactive ion etching, with process parameters set as follows: inductively coupled plasma power: 400-800 W, radio frequency power: 50-200 W, working pressure: 3-15 mTorr, oxygen flow rate: 20-50 sccm, etching time: 5-30 min, and etching rate: 150-200 nm/min;
in a case where the first layer of metal mask is made of chromium, the wet etchant is a mixed solution containing 5-10 vol% of 65-70% nitric acid solution, 30-50 g/L cerium ammonium nitrate, and deionized water; in a case where the first layer of metal mask is made of aluminum, the wet etchant is a tetramethylammonium hydroxide solution with a concentration of 0.5-10 wt%, and an etching rate of the wet etching is 5-20 nm/s; and
the second reactive ion etching is implemented via inductively coupled plasma reactive ion etching, with process parameters set as follows: inductively coupled plasma power: 400-800 W, radio frequency power: 50-200 W, working pressure: 3-15 mTorr, oxygen flow rate: 20-50 sccm, etching time: 5-10 min, and etching rate: 150-200 nm/min.

8. The fabrication method of the high-aspect-ratio double-layer diamond nanostructure according to claim 6, wherein after completing the second reactive ion etching, the fabrication method further comprises:
removing the second layer of metal mask and cleaning the single crystal diamond with an acid solution, wherein
in a case where the second layer of metal mask is made of titanium, removing the second layer of metal mask with a buffered oxide etchant, and in a case where the second layer of metal mask is made of gold, removing the second layer of metal mask with aqua regia;
the acid solution is a mixture of concentrated sulfuric acid and concentrated nitric acid, with a volume ratio of concentrated sulfuric acid to concentrated nitric acid of 3:1; and
a cleaning operation comprises: placing the single crystal diamond in the acid solution and heating for acid boiling at 150-200°C.

9. The fabrication method of the high-aspect-ratio double-layer diamond nanostructure according to claim 1, wherein operations of surface pretreatment comprise:
performing double-sided mechanical fine polishing on the single crystal diamond until a roughness Ra of the surface of the single crystal diamond is less than 1 nm; and
conducting chemical treatment on the polished single crystal diamond to remove surface impurities, wherein
an operation of the chemical treatment comprises: placing the single crystal diamond in an acid solution and heating for acid boiling at 150-200°C, and the acid solution is a mixture of concentrated sulfuric acid and concentrated nitric acid, with a volume ratio of concentrated sulfuric acid to concentrated nitric acid of 3:1.

10. The fabrication method of the high-aspect-ratio double-layer diamond nanostructure according to claim 1, wherein prior to performing the electron beam lithography, the fabrication method further comprises:
cleaning the surface of the single crystal diamond, wherein
operations of the cleaning comprise:
cleaning the single crystal diamond with a piranha solution; and
subjecting the single crystal diamond to ultrasonic treatment sequentially with acetone, isopropanol, and deionized water.
